(19) United States
(12) Patent Application Publication
(10) Pub. No.: US 2026/0206349 A1
(43) Pub. Date: Jul. 16, 2026

(54) IMAGE SENSOR WITH INSULATING FILM HAVING OPEN REGION

(71) Applicant: SAMSUNG ELECTRONICS CO., LTD., Suwon-si (KR)

(72) Inventors: Younghwan CHOI, Suwon-si (KR); Chanhyung Kim, Suwon-si (KR); Jongwon Choi, Suwon-si (KR); Changrai Kim, Suwon-si (KR); Hyeonsu Bae, Suwon-si (KR); Sewon SEO, Suwon-si (KR); Yeonjin Lee, Suwon-si (KR); Eunsang Cho, Suwon-si (KR)

(73) Assignee: SAMSUNG ELECTRONICS CO., LTD., Suwon-si (KR)

(21) Appl. No.: 19/443,719

(22) Filed: Jan. 8, 2026

(30) Foreign Application Priority Data
Jan. 13, 2025 (KR) 10-2025-0004630

(51) Int. Cl. H10F 39/00; H10F 39/12

(52) U.S. Cl. CPC H10F 39/807; H10F 39/199; H10F 39/805; H10F 39/8053; H10F 39/809; H10F 39/811

(57) ABSTRACT

An image sensor includes a stack structure including an active pixel region and a light-blocking region outside of the active pixel region. The stack structure includes a first substrate having a first surface and a second surface opposite to the first surface, and including unit pixels, a PD isolation pattern extending in a vertical direction to the first substrate in the active pixel region and the light-blocking region, and defining the unit pixels, an anti-reflective laminate including a lower insulating film and a conductive film sequentially stacked on the second surface, a light blocking layer on the anti-reflective laminate in the light-blocking region, and a second substrate including logic elements configured to drive the unit pixels. The lower insulating film includes an open region opening the second surface in the light-blocking region. The conductive film is coupled with the second surface through the open region of the lower insulating film.

### CROSS-REFERENCE TO RELATED APPLICATIONS

This application claims priority under 35 USC § 119 to Korean Patent Application No. 10-2025-0004630, filed on January 13, 2025, in the Korean Intellectual Property Office, the disclosure of which is incorporated by reference herein in its entirety.

### BACKGROUND

### Field

The present disclosure relates generally to image sensors, and more particularly, to an image sensor with an insulating film having an open region.

### Description of Related Art

Recent developments in industries like the computer industry and/or the communications industry may have increased demand for image sensors having relatively improved performance. For example, there may be increasing demand for image sensors in various fields such as, but not limited to, digital cameras, camcorders, personal communication systems (PCS), game devices, security cameras, medical micro cameras, or the like.

An image sensor may refer to a device that may convert an optical image signal into an electrical signal. For example, a complementary metal-oxide-semiconductor (CMOS) image sensor (CIS) may include a plurality of pixels that may be arranged two-dimensionally (2D). Each of the pixels may include a photoelectric conversion region, such as, but not limited to, a photodiode.

### SUMMARY

One or more example embodiments of the present disclosure provide an image sensor having improved electrical characteristics and reliability, when compared to related image sensors.

According to an aspect of the present disclosure, an image sensor includes a stack structure including an active pixel region and a light-blocking region outside of the active pixel region. The stack structure further includes a first substrate having a first surface and a second surface opposite to the first surface, and including photodiodes (PDs), each of unit pixels including at least one of the PDs, a photodiode (PD) isolation pattern penetrating at least a portion of the first substrate in the active pixel region and the light-blocking region, and separating the PDs, an anti-reflective laminate in the light-blocking region including a lower insulating film and a conductive film sequentially stacked on the second surface of the first substrate, a light blocking layer on the anti-reflective laminate, and a second substrate on the first surface of the first substrate and including logic elements configured to drive the unit pixels. Each of the unit pixels includes a PD. The lower insulating film includes an open region opening the second surface of the first substrate in the light-blocking region. The conductive film is coupled with the second surface of the first substrate through the open region of the lower insulating film.

According to an aspect of the present disclosure, an image sensor includes a stack structure including an active pixel region and a light-blocking region outside of the active pixel region. The stack structure includes a first substrate having a first surface and a second surface opposite to the first surface, and including photodiodes (PDs), each of unit pixels including at least one of the PDs, a PD isolation pattern penetrating at least a portion of the first substrate in the active pixel region and the light-blocking region, and separating the PDs, backside contacts extending from the second surface of the first substrate in the light-blocking region and coupled with a region of the PD isolation pattern, an anti-reflective laminate in the light-blocking region including a first insulating film, a conductive film, and a second insulating film sequentially stacked on the second surface of the first substrate, color filters corresponding to each of the unit pixels and disposed on the anti-reflective laminate of the active pixel region, a light blocking layer on the anti-reflective laminate, and a second substrate on the first surface of the first substrate, and including logic elements configured to drive the unit pixels. The first insulating film includes an open region opening another region of the PD isolation pattern in the light-blocking region. The conductive film is coupled with another region of the PD isolation pattern through the open region of the first insulating film.

According to an aspect of the present disclosure, an image sensor includes a stack structure including an active pixel region in which a plurality of pixels are defined, and a light-blocking region outside of the active pixel region. The stack structure further includes a first substrate having a first surface and a second surface, opposite to the first surface, and including photodiodes (PDs), each of the plurality of pixels including at least one of the PDs, a PD isolation pattern penetrating at least a portion of the first substrate in the active pixel region and the light-blocking region, and separating the PDs, an anti-reflective laminate including a first insulating film, a conductive film, and a second insulating film sequentially stacked on the second surface of the first substrate, a first wiring structure on the first surface of the first substrate, and including a first wiring layer and a first interlayer dielectric, a second substrate disposed on the first wiring structure, and including logic elements for driving the plurality of pixels, and a second wiring structure between the second substrate and the first wiring structure, and including a second wiring layer and a second interlayer dielectric. The first insulating film includes an open region opening at least one of the second surface of the first substrate or the PD isolation pattern in the light-blocking region. The conductive film is coupled with a region of the at least one of the second surface or the PD isolation pattern opened through the open region.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description, taken in conjunction with the accompanying drawings, in which:

FIG. 1 is an exploded perspective view illustrating an image sensor, according to an embodiment;

FIG. 2 is a plan view of portion 'A' of the image sensor of FIG. 1, according to an embodiment;

FIG. 3 is a cross-sectional view taken along line Ⅰ–Ⅰ' of the portion 'A' of the image sensor of FIG. 2, according to an embodiment;

FIG. 4A is an enlarged cross-sectional view of portion 'B' of FIG. 3, according to an embodiment;

FIG. 4B is a plan view corresponding to the cross-sectional view of portion 'B' of FIG. 4A, according to an embodiment;

FIG. 5 is a plan view illustrating a pixel region of the image sensor of FIG. 1, according to an embodiment;

FIGS. 6A and 6B are plan views respectively illustrating a pixel region of an image sensor, according to an embodiment;

FIG. 7A is an enlarged cross-sectional view illustrating a portion of an image sensor, according to an embodiment;

FIG. 7B is a plan view corresponding to the cross-section of FIG. 7A, according to an embodiment;

FIG. 8 is a cross-sectional view illustrating an image sensor, according to an embodiment;

FIG. 9A is an enlarged cross-sectional view illustrating the portion 'B2' of FIG. 8, according to an embodiment;

FIG. 9B is a plan view corresponding to the cross-section of FIG. 9A, according to an embodiment;

FIG. 10 is a plan view illustrating a pixel region of the image sensor of FIG. 8, according to an embodiment;

FIGS. 11A and 11B are plan views illustrating a pixel region of an image sensor, according to an embodiment; and

FIGS. 12A and 12B are enlarged cross-sectional views illustrating a portion of an image sensor, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “AlOₓ”, “HfOₓ”, “SiN”, “SiO”, “SiON”, “SnO₂”, “TaN”, “TaO₂”, “TiN”, “TiO₂”, “ZnO”, “ZrO₂”, or the like may refer to a material made of elements included in each of the terms and is not a chemical formula representing a stoichiometric relationship.

Hereinafter, various embodiments of the present disclosure are described with reference to the accompanying drawings.

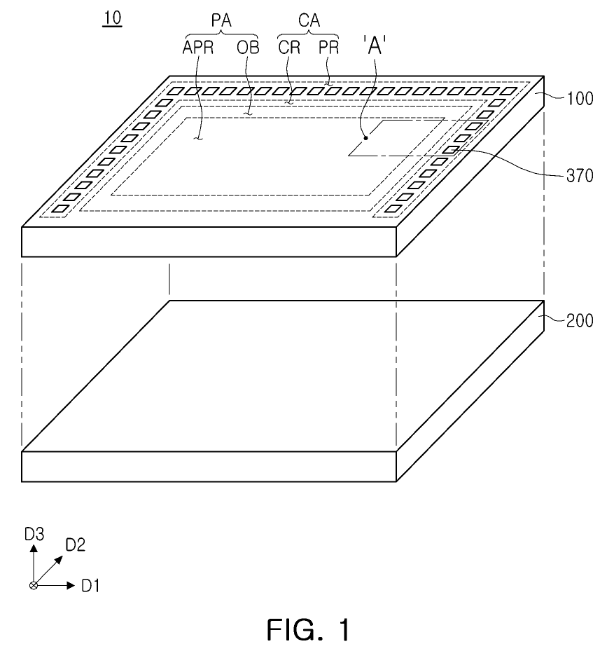

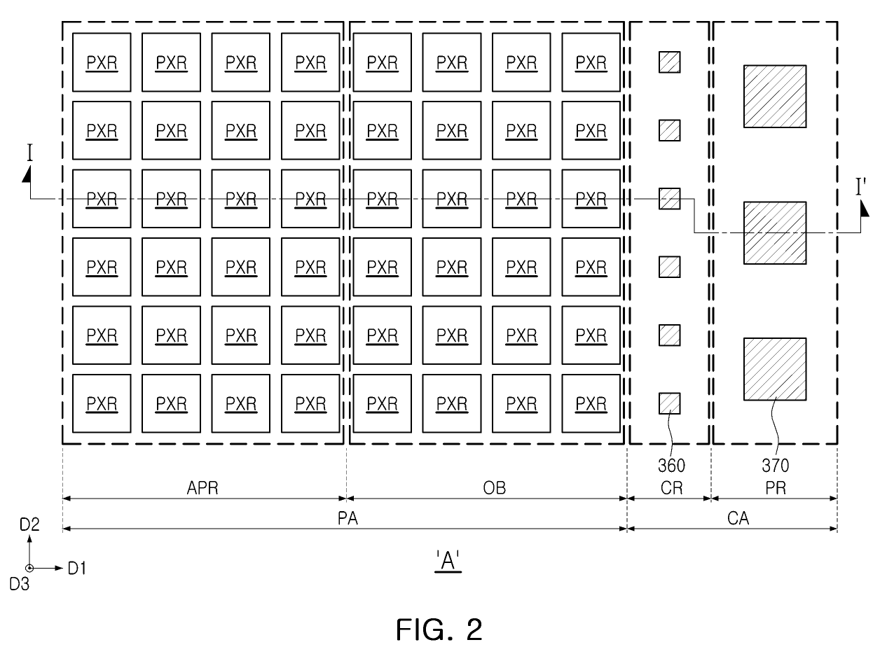

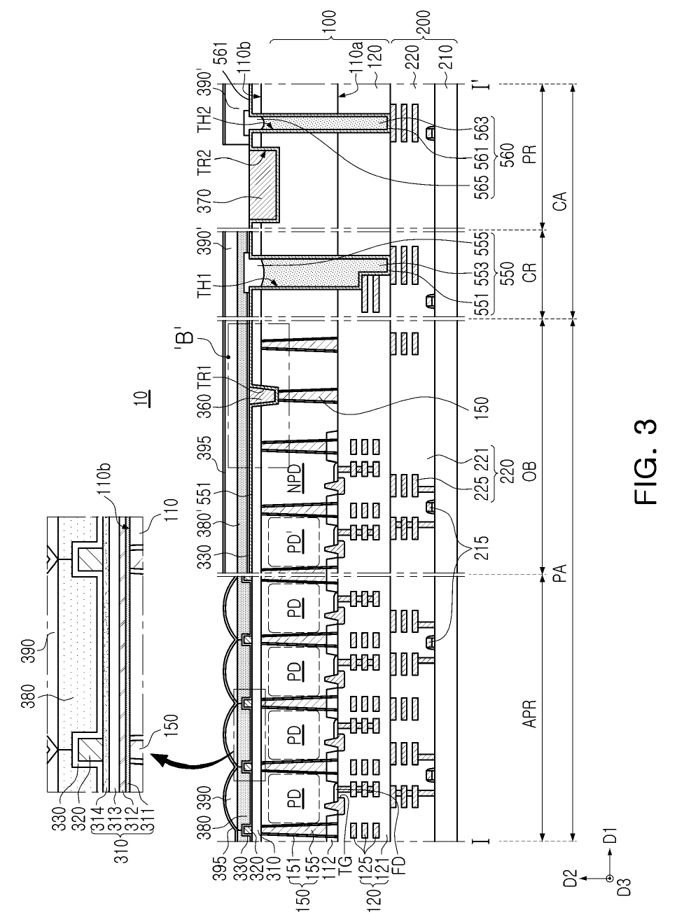

FIG. 1 is an exploded perspective view illustrating an image sensor, according to an embodiment. FIG. 2 is a plan view of portion 'A' of the image sensor of FIG. 1, according to an embodiment. FIG. 3 is a cross-sectional view taken along line I–I' of the portion 'A' of the image sensor of FIG. 2, according to an embodiment.

Referring to FIGS. 1 to 3, an image sensor 10, according to the present disclosure, may include a stack structure having a first substrate structure 100 and a second substrate structure 200 that may be electrically connected to each other. The first substrate structure 100 may include a first substrate 110 having a pixel region PA and a first wiring structure 120 on a first surface 110a of the first substrate 110. The second substrate structure 200 may include a second substrate 210 having an upper surface on which logic elements 215 may be disposed, and a second wiring structure 220 in contact with the first wiring structure 120 on the second substrate 210. As used herein, the first substrate structure 110 may also be referred to as a sensor chip, and the second substrate structure 200 may also be referred to as a logic chip.

The image sensor 10, according to the present disclosure, may include a pixel region PA in which a plurality of pixels may be arranged two-dimensionally (2D) from a planar perspective, and a peripheral region CA outside of the pixel region PA.

As shown in FIG. 1, the pixel region PA may include an active pixel region APR located at the center of the pixel region and a light-shielding region OB surrounding the active pixel region APR. Each of the active pixel region APR and the light-blocking region OB may include a plurality of pixels PXRs receiving light and generating an electrical signal. The pixels PXRs of the active pixel region APR may include active pixels as a whole.

A light-blocking region OB may be disposed around the active pixel array region APR. The light-blocking region OB may include optical black pixels from which light may be blocked to generate an optical black signal. In some embodiments, some pixels PXRs of the light-blocking region OB (e.g., pixel regions outside thereof) may be and/or may include dummy pixels.

The peripheral region PA may surround a pixel region PA (e.g., a light-blocking region OB). The peripheral region PA may include, for example, a connection region CR and a pad region PR. The connection region CR may be disposed adjacent to the light-blocking region OB. In an embodiment, first connection structures 550 connecting the first substrate structure 100 and the second substrate structure 200 may be formed in the connection region CR.

The pad region PR may be disposed around the light-blocking region OB. In an embodiment, the pad region PR may be disposed adjacent to an edge of the image sensor 10. Although FIGS. 1-3 depict the pad region PR as being disposed along three (3) sides of the image sensor 10, embodiments of the present disclosure are not limited in this regard. For example, the pad region PR may be disposed to surround two (2) sides or all sides of the image sensor 10. The pad region PR may include a plurality of external bonding pads 370 for connection with an external device, and may be configured to transmit and/or receive electrical signals between the image sensor 10 and the external device.

As described with reference to FIG. 3, the image sensor 10, according to an embodiment, may include a stack structure having a first substrate structure 100 and a second substrate structure 200.

The first substrate structure 100 may include a first substrate 110 having a first surface 110a and a second surface 110b located opposite to each other, a front optical structure on the second surface 110b of the first substrate 110, and a first wiring structure 120 on the first surface 110a of the first substrate 110. The first substrate structure 100 may include a first substrate 110 having a first surface 110a and a second surface 110b located opposite to each other, a front optical structure on the second surface 110b of the first substrate 110, and a first wiring structure 120 on the first surface 110a of the first substrate 110.

The first substrate structure 100 may also be referred to as a sensor chip, and the second substrate structure 200 may also be referred to as a logic chip. Although the image sensor 10 is exemplified as a stack structure having two (2) substrates, embodiments of the present disclosure are not limited thereto. For example, the image sensor 10 may include a stack structure having three (3) or more substrates. As another example, at least a portion of transistors for a pixel circuit may be implemented on a separate substrate, other than the first substrate 110.

Referring to FIG. 3, the first substrate 110 may include a device separation pattern 112 defining an active region ACT on a first surface 110a, and pixel circuit elements such as, but not limited to, a vertical transfer gate TG, on the active region. A plurality of photodiodes PDs (or photoelectric conversion regions) may be disposed within the substrate 110.

The plurality of pixels PXRs may be and/or may include regions receiving light from the outside and converting the light into an electrical signal. For example, the plurality of pixels PXRs may include a photodiode PD for receiving external light and transistors forming a pixel circuit for converting photocharges accumulated in the photodiode PD into electrical signals.

The first substrate 110 may be and/or may include a semiconductor substrate. For example, the first substrate 110 may be a bulk silicon or a silicon-on-insulator (SOI) substrate. In an embodiment, the plurality of pixels PXR may be arranged planarly (e.g., in a matrix), including a first direction D1 and a second direction D2 within the pixel region PA. In each pixel region, at least one photodiode PD may be disposed within the first substrate 110. The photodiodes PDs may generate charges in proportion to an amount of light incident from the outside. For example, the photodiodes PDs may be and/or may include photo diodes, photo transistors, photo gates, pinned photo diodes, organic photo diodes, or the like.

In an embodiment, the photodiodes PDs may be disposed in an active pixel region APR provided as an active pixel, and in a light-blocking region OB. In the light-blocking region OB, a first reference region PD' may be configured substantially similar and/or the same as the photodiodes PDs and a second reference region (e.g., a dummy photodiode NPD) not forming a photodiode may be provided. In the light-blocking region OB, the first and second reference regions PD' and NPD may be disposed within the first substrate 110, and may be separated by the PD isolation pattern 150.

The image sensor 10, according to an embodiment, may be and/or may include a backside-surface illumination (BSI) image sensor. A second surface 110b of the first substrate 110 may be provided as a light receiving surface into which light is incident. In the active pixel region APR and the light-blocking region OB, the first substrate 110 may further include a PD isolation pattern 150 defining unit pixels (e.g., a plurality of pixels PXRs). The PD isolation pattern 150 may have a structure penetrating through the first substrate 101, so that crosstalk between adjacent pixels due to light incident obliquely may be prevented and/or reduced, when compared to a related image sensor.

Referring to FIG. 2, the PD isolation pattern 150 may be disposed in a grid shape to separate a plurality of photodiodes PDs in a plan view. The PD isolation pattern 150 may penetrate through at least a portion of the first substrate 110.

In an embodiment, the PD isolation pattern 150 may have a structure extending from the first surface 110a of the first substrate 101 to the second surface 110b thereof. In some embodiments, the PD isolation pattern 150 may have a structure extending from the second surface 110b of the first substrate 101 to the first surface 110a thereof. The PD isolation pattern 150 may be formed by forming a trench in the first substrate 110, forming an insulating barrier 151 inside the trench, and filling a conductive material 155. The insulating barrier 151 may be disposed on a sidewall of the trench, and may be interposed between the conductive material 155 and the first substrate 110. For example, the insulating barrier 151 may include silicon oxide (SiO), silicon nitride (SiN), or silicon oxynitride (SiON). For example, the conductive material 155 may include a polysilicon doped with impurities (e.g., boron (B), phosphorus (P), arsenic (As), or the like).

The first wiring structure 120 may include a first interlayer dielectric 121 and a first wiring layer 125. The number of layers and arrangement of the first wiring layer 125 illustrated in the drawing are merely exemplary. For example, the first interlayer dielectric 121 may include at least one of silicon oxide (SiO), silicon nitride (SiN), silicon oxynitride (SiON), and a low-κ material having a lower dielectric constant than silicon oxide (SiO). For example, the first wiring layer 125 may include at least one of tungsten (W), copper (Cu), aluminum (Al), gold (Au), silver (Ag), and alloys thereof.

The second substrate 210 may be and/or may include a bulk silicon or SOI substrate, substantially similar to and/or the same as the first substrate 110. Logic elements 215 may be disposed on the second substrate 210. The logic elements 215 may include a circuit providing a constant signal to each pixel PX of the active pixel region APR and/or controlling an output signal from each unit pixel. For example, the logic elements 215 may include various transistors including, but not limited to, a control register block, a timing generator, a ramp signal generator, a row driver, a readout circuit, and/or an input/output buffer (I/O) circuit.

The second wiring structure 220 may be disposed between the first wiring structure 120 of the first substrate structure 100 and the second substrate 210. The second wiring structure 220 may include a second interlayer dielectric 221 and a second wiring layer 225. The number of layers and arrangement of the second wiring layer 225 are merely exemplary. The second wiring layer 225 may include vias electrically connecting the logic elements 215. For example, the second interlayer dielectric 221 may include at least one of silicon oxide (SiO), silicon nitride (SiN), silicon oxynitride (SiON), and a low-κ material having a lower dielectric constant than silicon oxide (SiO). The second wiring layer 225 may include, for example, at least one of tungsten (W), copper (Cu), aluminum (Al), gold (Au), silver (Ag), and alloys thereof.

In an embodiment, the first wiring structure 120 may be bonded to the second wiring structure 220. In some embodiments, each of the first and second wiring structures 120 and 220 may include a bonding insulating layer disposed on a surface to be bonded. In addition, the first and second substrate structures 100 and 200 may be coupled to each other by first and second connection structures 550 and 560 penetrating through the first substrate structure 100 and may be connected to the second substrate structure 200. The first and second connection structures 550 and 560 may be respectively disposed in the connection region CR and the pad region PR, and may electrically connect the first wiring 125 and the second wiring 225.

Referring to FIG. 3, the first substrate structure 100 may include an anti-reflective laminate 310 formed on the second surface 110b of the first substrate 110.

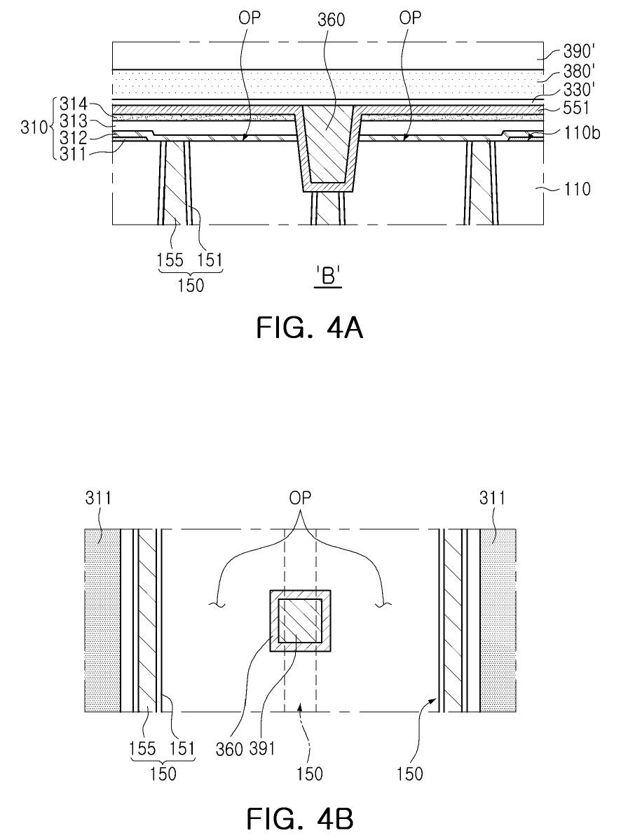

The anti-reflective laminate 310 may serve to suppress reflection of incident light, and increase an amount of light incident on the photodiode PD. The anti-reflective laminate 310 may include multiple layers as shown in FIG. 4A, and a refractive index and thickness of each film may be appropriately adjusted to suppress and/or reduce the reflection of incident light, when compared to related image sensors.

The anti-reflective laminate 310 may be disposed entirely in the pixel region PA, but may be selectively disposed in the peripheral region CA. For example, the anti-reflective laminate 310 may not be disposed on the backside contact 360, the first connection structure 550, the second connection structure 560, and the external bonding pad 370.

The anti-reflective laminate 310 may include at least one conductive film 312.

Referring to FIG. 4A, the anti-reflective laminate 310 may include a first insulating film 311, a conductive film 312, a second insulating film 313, and a third insulating film 314, sequentially stacked on the second surface 110b of the substrate 110. Since the conductive film 312 is electrically floating due to a first insulating film 311 located therebelow (which may also be referred to as a lower insulating film), a large amount of charges may accumulate within the conductive film 312 in a manufacturing process (e.g., a deposition process of the anti-reflective laminate 310), which may have a disadvantageous effect.

The conductive film 312 may be and/or may include a metal oxide having a specific refractive index and electrical conductivity. In some embodiments, the metal oxide may have electrical conductivity by being doped with impurities and/or by oxygen vacancies. For example, impurity doping may be performed by doping metals such as, but not limited to, aluminum (Al), gallium (Ga), indium (In), or by doping metallic elements (e.g., niobium (Nb), titanium (Ti), or the like) or non-metallic elements (e.g., nitrogen (N), carbon (C), or the like). In addition, oxygen vacancies may be obtained by controlling an oxygen composition ratio, and free electrons may be formed by oxygen vacancies, which may increase electrical conductivity. For example, the conductive film 312 may include titanium oxide (TiO₂), tin oxide (SnO₂), tantalum oxide (TaO₂), or zinc oxide (ZnO) satisfying these conditions. As another example, the first insulating film 311, the second insulating film 313, and the third insulating film 314 may include, but not be limited to, an aluminum oxide (AlOₓ), a hafnium oxide (HfOₓ), a silicon oxide (SiO), or a silicon nitride (SiN).

In some embodiments, the first insulating film 311 may be and/or may include an aluminum oxide (AlOₓ), and the conductive film 312 may include, but not be limited to, titanium oxide (TiO₂) or tantalum oxide (TaO₂). In addition, the second insulating film 313 and the third insulating film 314 may include, but not be limited to, silicon oxide (SiO) and hafnium oxide (HfOₓ), respectively. As used herein, the silicon oxide may be and/or may include tetraethly orthosilicate (TEOS), plasma enhanced silicon oxide (PEOX), or a porous low-κ material.

In an embodiment, in order to secure an electrical path for discharging the charges accumulated in the conductive film 312 (e.g., a discharge path), as illustrated in FIGS. 4A and 4B, the anti-reflective laminate 310 may be structurally changed in the light-blocking region OB. FIG. 4B is a plan view corresponding to the cross-sectional view of portion 'B' of FIG. 4A, according to an embodiment, illustrating a pattern of the first insulating film 311.

Referring to FIGS. 4A and 4B, the first insulating film 311 may be configured to have an open region OP opening an electrical contact region in a light-blocking region OB. A conductive film 312 formed on a first insulating film 311 may be connected to an electrical contact region through the open region OP of the first insulating film 311, and charges accumulated in the conductive film 312 may be released through such an open region OP.

In an embodiment, the electrical contact region defined by the open region OP may include a region of the second surface 110b of the first substrate 110 around a backside contact 360, and may extend to a portion of the PD isolation pattern 150 around the backside contact 360. A conductive material 155 of the PD isolation pattern 150 may be exposed and may be in contact with the conductive film 312. The PD isolation pattern 150 opened by the open region OP may be provided as a high-quality discharge path for the conductive film 312.

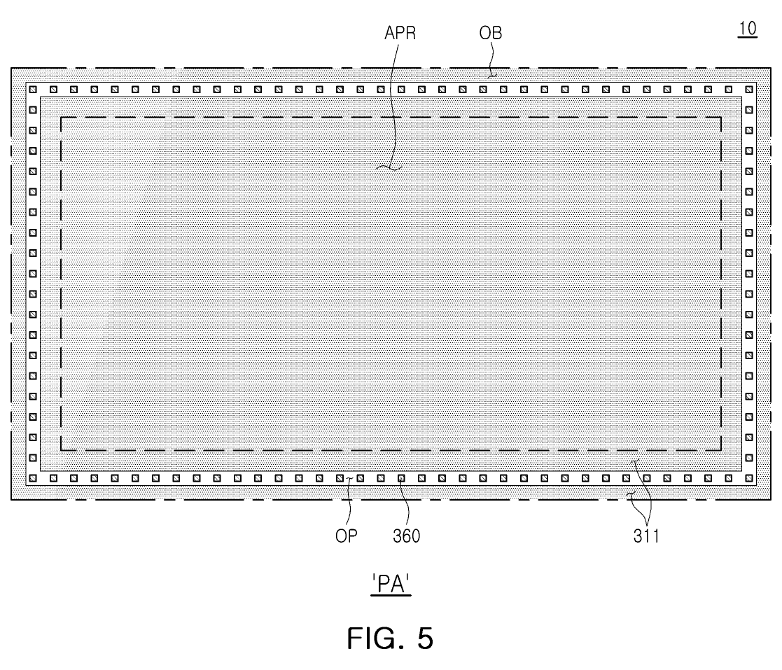

Referring to FIG. 5 together with FIG. 4B, the open region OP of the first insulating film 311 may be formed continuously according to the arrangement of the backside contacts 360, and may have a width enough to open a portion of the PD isolation pattern 150 around the backside contacts 360. In addition, the open region OP of the first insulating film 311 may extend in accordance with the arrangement of the backside contacts 360 in the light-blocking region OB to surround the active pixel region APR.

The anti-reflective laminate 310 may secure a stable discharge path through the light-blocking region OB located on the entire periphery of the active pixel region APR.

Referring to FIG. 3, in the pixel region PA, the first substrate structure 100 may include a grid pattern 320 on the anti-reflective laminate 310, a first protective layer 330 covering the anti-reflective laminate 310 and the grid pattern 320, a color filter layer 380 separated by the grid pattern 320, and microlenses 390 on the color filter layer 380.

A grid pattern 320 may have a mesh shape in a planar manner, and may be vertically overlapped with the PD isolation pattern 150 in the active pixel region APR. In some embodiments, the grid pattern 320 may include a conductive pattern. The conductive pattern may prevent and/or reduce a possibility of an electrostatic discharge (ESD) failure, when compared to related image sensors. However, since the second and third insulating films 313 and 314 are located above the conductive film 311 in the anti-reflective laminate 310, it may be difficult to contribute to releasing charges accumulated in the conductive film. The conductive pattern may include, for example, at least one of titanium (Ti), titanium nitride (TiN), tantalum (Ta), tantalum nitride (TaN), tungsten (W), aluminum (Al), or copper (Cu). In some embodiments, the grid pattern 320 may include a low refractive index pattern. The low refractive index pattern may improve the quality of the image sensor by improving the light collection efficiency by refracting and/or reflecting light incident obliquely. The low refractive index pattern may include a low refractive index material having a refractive index lower than that of silicon (Si). For example, the low refractive index pattern may include at least one of a silicon oxide (SiO), an aluminum oxide (AlOₓ), a tantalum oxide (TaO₂), and/or a combination thereof.

A first protective layer 330 may be conformally formed along an upper surface of the anti-reflective laminate 310 and a side and upper surface of the grid pattern 320. The first protective layer 330 may prevent damage to the grid pattern 320. For example, the first protective layer 330 may include at least one of an silicon oxide (SiO), a silicon nitride (SiN), a silicon oxynitride (SiON), an aluminum oxide (AlOₓ), a hafnium oxide (HfOₓ), or a combination thereof.

A color filter layer 380 may be disposed between grid patterns 320 on the anti-reflective laminate 310. The color filter layer 380 may be arranged to correspond to each unit pixel of the active pixel region APR. The color filter layer 380 may have various color filters depending on the unit pixel. For example, the color filter layer 380 may include, but not be limited to, a red (R) color filter, a green (G) color filter, or a blue (B) color filter. In some embodiments, the color filter layer 380 may be arranged in a Bayer pattern. However, this is merely an example, and the color filter layer 380 may include a yellow filter, a magenta filter, and a cyan filter, and may further include a white filter.

A microlens layer 390 may be disposed on the color filter layer 380. The microlens layer 390 may include microlenses arranged to correspond to each unit pixel of the pixel array region PA. Each of the microlenses may have a convex shape, and may have a predetermined radius of curvature. Accordingly, the microlens may focus light incident on the photodiodes PDs. The microlens layer 390 may include, for example, a light-transmitting resin. In some embodiments, the microlens layer 390 may extend to a portion of the peripheral region (e.g., the light-blocking region OB).

In addition, referring to FIG. 3, in the light-blocking region OB, a first conductive layer 351, a first protective layer 330, and a light-blocking filter layer 380' may be disposed on the anti-reflective laminate 310. In some embodiments, the light-blocking filter layer 380' may extend from the light-blocking region OB to the connection region CR on the first conductive layer 551, and may be provided as a light-blocking structure blocking light together with the first conductive layer 551. The light-blocking filter layer 380' may be formed together with the color filter layer 380, and may have a substantially similar and/or the same thickness as the color filter layer 380. However, embodiments of the present disclosure are not limited thereto. The light-blocking filter layer 380' may include a blue color filter and/or a black filter.

In some embodiments, the light-blocking region OB may be used to remove noise signals due to dark current. For example, in a state in which light is blocked by the first conductive layer 551 and the light-blocking filter layer 380', a first reference region PD' including a photodiode may be used as a reference pixel for noise removal by the photodiode. In some embodiments, the light-blocking region OB may be used to remove noise signals due to dark current. For example, in a state in which light is blocked by the first conductive layer 551 and the light-blocking filter layer 380', a first reference region PD' including a photodiode may be used as a reference pixel for noise removal by the photodiode.

A backside pad 360 may be disposed in the light-blocking region OB. The backside contact 360 may fill a first trench TR1. The backside contact 360 may include a metal material (e.g., aluminum (Al)). The backside contact 360 may be connected to the PD isolation pattern 150. A bias may be applied to the conductive material 155 of the PD isolation pattern 150 through the backside contact 360. In addition, the first conductive layer 551 may be connected to the PD isolation pattern 150. The first conductive layer 551 may include a metal material (e.g., tungsten (W)). The first conductive layer 551 may block light incident into the light-blocking region OB.

In the connection region CR, a first connection structure 550 may be disposed. The first connection structure 550 may include a first conductive layer 551, a first separation pattern 553, and a first capping pattern 555. The first conductive layer 551 may conformally extend to an inner wall of a first through-hole TH1 on the second surface 110b of the first substrate 110. The first conductive layer 551 may penetrate through the first substrate 110 and the first wiring structure 120 (e.g., the first substrate structure 100) to connect the first wiring layer 125 and the second wiring layer 225 to each other.

In the pad region PR, a second connection structure 560 and an external bonding pad 392 may be disposed. The second connection structure 560 may include a second conductive layer 561, a second separation pattern 563, and a second capping pattern 565. The second conductive layer 561 may be formed to cover the anti-reflective laminate 310 on the second surface 110b of the first substrate 110. The second conductive layer 561 may conformally cover an inner wall of a second through-hole TH2. The second conductive layer 561 may penetrate through the first substrate 110 and the first wiring structure 120 (e.g., the first substrate structure 100) to connect the first wiring layer 125 and the second wiring layer 225 to each other. The second conductive layer 561 may include a metal material (e.g., tungsten (W)) similar to the first conductive layer 551.

The external bonding pad 370 may fill a second trench TR2. The external bonding pad 370 may include a metal material (e.g., aluminum (Al)). The external bonding pad 370 may serve as an electrical connection path between the image sensor 10 and an external element. The external bonding pad 370 may be connected to the logic elements 215 of the second substrate 210 through the second conductive layer 561 of the second connecting structure 560 and the second wiring layer 225. An electrical signal generated from the photodiodes PDs of the pixel array region PA may be transmitted to an external element through the first and second wiring layers 125 and 225, the second conductive layer 561, and the external bonding pad 370.

Referring to FIG. 3, a transparent planarization layer 390' may be formed in the light-blocking region OB and the connection region CR, and the pad region PDR. The transparent planarization layer 390' may cover a light-blocking filter layer 380' and a second connection structures 560 on the second surface 110b of the first substrate 110, thereby providing a planar upper surface.

The transparent planarization layer 390' may include a light-transmitting inorganic material. In some embodiments, the transparent planarization layer 390' may include an oxide such as, but not limited to, tetra ethyl ortho silicate (TEOS). An example embodiment thereof is not limited thereto and the transparent planarization layer 390' may include spin-on hardmask (SOH), flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable chemical vapor deposition (FCVD) oxide, or a combination thereof. The transparent planarization layer 390' may be formed to have a planar upper surface using a chemical vapor deposition, a fluid chemical vapor deposition (CVD) process, or a spin coating process. The transparent planarization layer 390' may include the same material as that of a microlens layer 390.

A second protective layer 395 may be disposed on the microlens layer 390. The second protective layer 395 may extend along a surface of the microlens layer 390. The second protective layer 395 may protect the microlens layer 390 from the outside. For example, the second protective layer 395 may protect the microlens 180 including an organic material by including an inorganic oxide film. In addition, the second protective layer 395 may improve the quality of the image sensor by improving the light collection efficiency of the microlens layer 390. The second protective layer 395 may include, for example, an inorganic oxide film (e.g., silicon oxide (SiO), titanium oxide (TiO₂), zirconium oxide (ZrO₂), hafnium oxide (HfOₓ), or a combination thereof). In some embodiments, the second protective layer 395 may include a low temperature oxide (LTO).

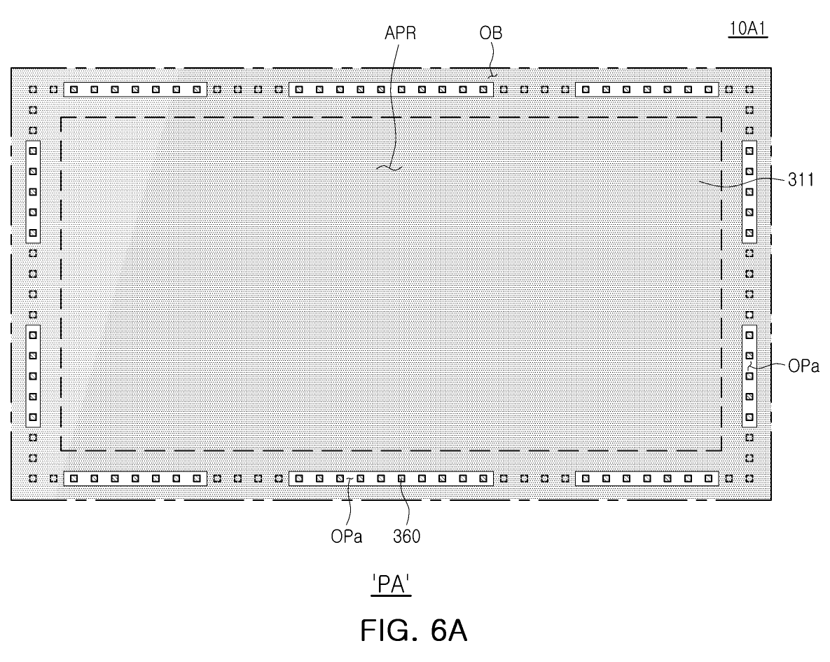

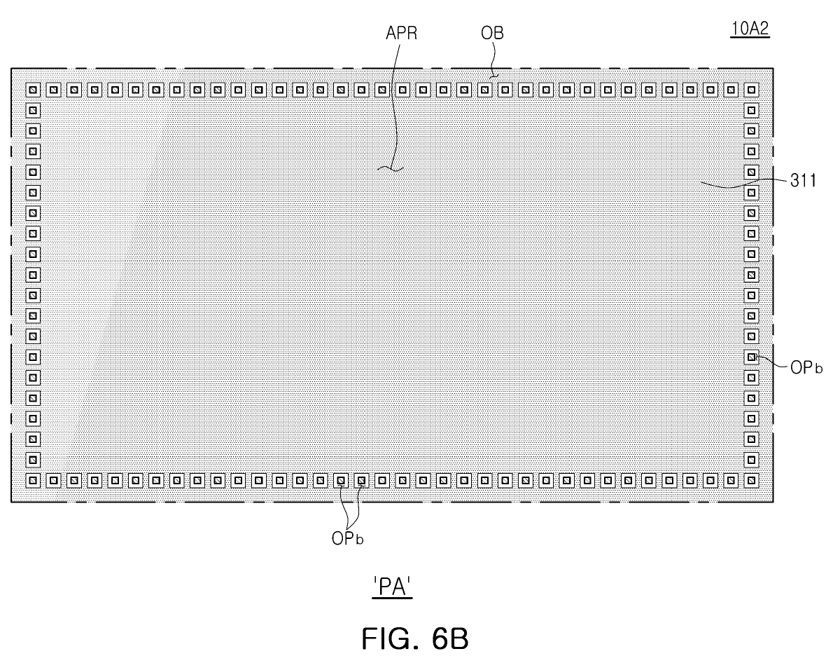

The first insulating film 311 may be exemplified as having an opening OP extending continuously to surround the active pixel region APR in the light-blocking region OB. However, embodiments of the present disclosure are not limited thereto. In some embodiments, the opening providing a discharge path for the conductive film 312 may be changed into various shapes as illustrated in FIGS. 6A and 6B.

Referring to FIG. 6A, an image sensor 10A1, according to an embodiment, may include a first insulating film 311 having an open region OPa of a different shape in a light-blocking region OB. The open region OPa of the first insulating film 311 may have a plurality of open patterns arranged along backside contacts 360. The plurality of open patterns may be formed to open adjacent plurality of backside contacts 360, and the PD isolation pattern 150 around the plurality of backside contacts 360, and may be arranged to surround an active pixel region APR.

Alternatively, referring to FIG. 6B, an image sensor 10A2, according to an embodiment, may include a first insulating film 311 having an open region of a different shape. The open region OPb of the first insulating film 311 may have open patterns corresponding to each of the backside contacts 360. The open patterns may be formed to open each of adjacent backside contacts 360 and the PD isolation pattern 150 around the plurality of backside contacts 360.

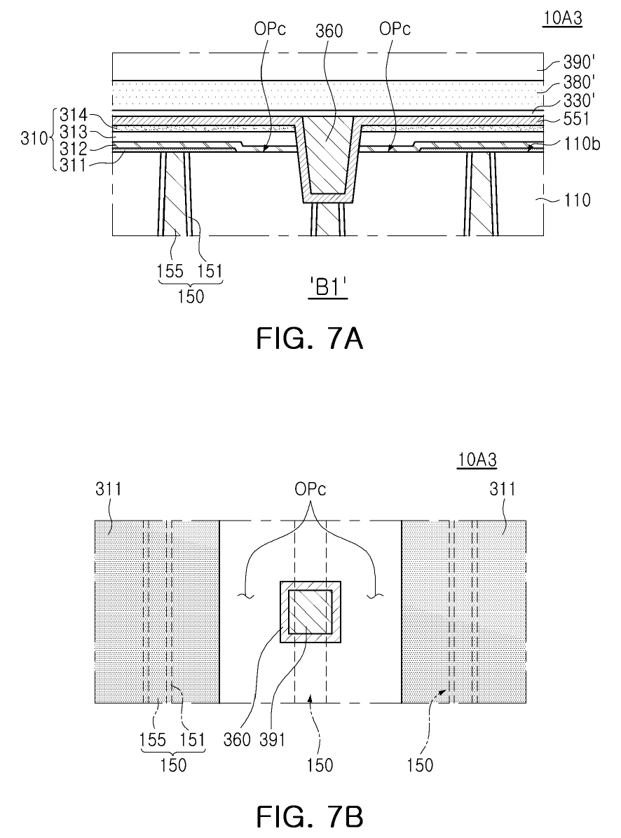

Although the open region of the first insulating film 311 has been exemplified as opening in a second surface 110b of the substrate 110 and the PD isolation pattern 150, to contact the conductive material 155 of the PD isolation pattern 150 with the conductive film 312, embodiments of the present disclosure are not limited in this regard. For example, an open region OPc may be configured to open only the second surface 110b of the substrate 110 without opening the PD isolation pattern 150, as described with reference to FIGS. 7A and 7B.

FIG. 7A is an enlarged cross-sectional view illustrating a portion of an image sensor, according to an embodiment. FIG. 7B is a plan view corresponding to the cross-section of FIG. 7A, according to an embodiment.

The image sensor 10A3 described with reference to FIGS. 7A and 7B may include and/or may be similar in many respects to the image sensor described above with reference to FIGS. 1-3, 4A, 4B, and 5, and may include additional features not mentioned above. For example, the open region OPc of the first insulating film 311 may be configured to open only the second surface 110b of the substrate 110 without opening the PD isolation pattern 150. Furthermore, components of the image sensor 10A3 may include and/or may be similar in many respects to the components of the image sensor 10 described above with reference to FIGS. 1-3, 4A, 4B, and 5, and may include additional features not mentioned above. Consequently, repeated descriptions of the image sensor 10A3 described above with reference to FIGS. 1-3, 4A, 4B, and 5 may be omitted for the sake of brevity.

The anti-reflective laminate 310 may include a first insulating film 311 having an open region OPc located around the backside contact 360, similar to the embodiments described above. However, unlike the embodiments described above, the open region OPc of the first insulating film 311 may open only the second surface 110b of the substrate 110 located around the backside contact 360, and may not open to the adjacent PD isolation pattern 150. The substrate 110 may be and/or may include a semiconductor substrate, such as, but not limited to, silicon (Si), for example, and since impurities may be doped in the process of forming a photodiode PD, a region adjacent to the second surface 110b of the substrate 110 may be provided as a conductive region that may be utilized as a discharge path. Consequently, the conductive film 312 may contact the open conductive region of the substrate 110 through the open region OPc of the first insulating film 311. The open region OPc of the first insulating film 311 may extend along the arrangement of the backside contacts 360 in a plan view, similar to the open region described with reference to FIGS. 4B and 5.

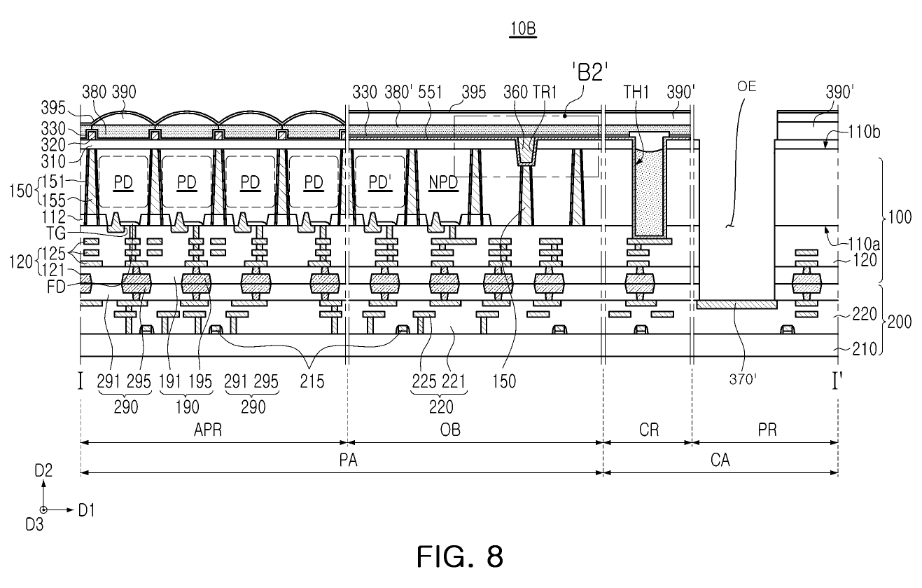

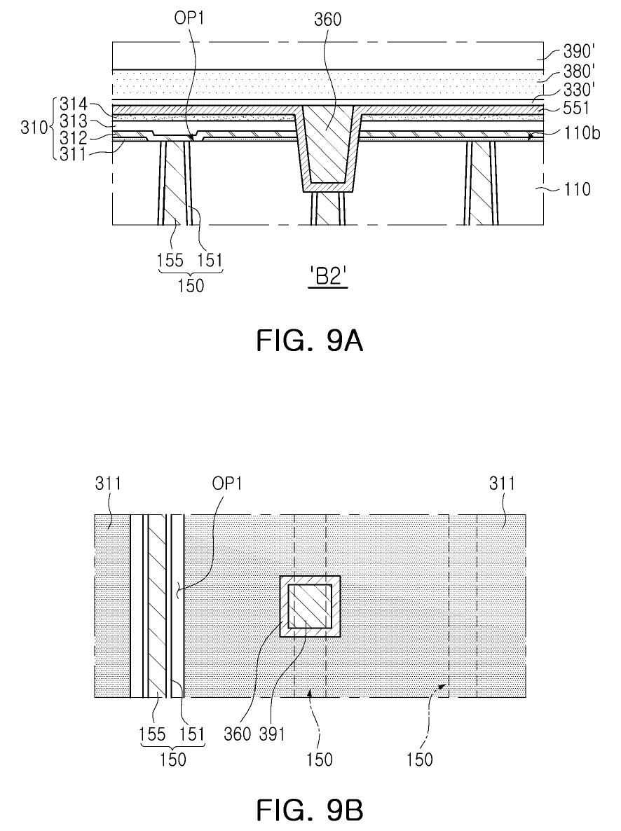

FIG. 8 is a cross-sectional side view illustrating an image sensor, according to an embodiment. FIG. 9A is an enlarged cross-sectional view illustrating a portion 'B2' of FIG. 8, according to an embodiment. FIG. 9B is a plan view corresponding to the cross-section of FIG. 9A, according to an embodiment.

The image sensor 10B described with reference to FIGS. 8, 9A, and 9B may include and/or may be similar in many respects to the image sensor described above with reference to FIGS. 1-3, 4A, 4B, and 5, and may include additional features not mentioned above. For example, the first substrate structure 100 and the second substrate structure 200 may be connected to each other by metal-dielectric bonding (which may also be referred to as hybrid bonding), an external bonding pad 370 may be disposed on the second substrate 210, and a pad opening OE may penetrate through the first substrate structure 100. Furthermore, components of the image sensor 10B may include and/or may be similar in many respects to the components of the image sensor 10 described above with reference to FIGS. 1-3, 4A, 4B, and 5, and may include additional features not mentioned above. Consequently, repeated descriptions of the image sensor 10B described above with reference to FIGS. 1-3, 4A, 4B, and 5 may be omitted for the sake of brevity.

In an embodiment, an external bonding pad 370' may be disposed on the second substrate structure 200 (e.g., the second substrate 210). The pad opening OE may penetrate through the first substrate structure 100, and the external bonding pad 370' may be opened by the pad opening OE. In an embodiment, since the external bonding pad 370' is formed directly on the second substrate 210, the second connection structures 560 (see FIG. 3) may not be used.

In an embodiment, since the external bonding pad 370' is formed directly on the second substrate 210, the second connection structures 560 (see FIG. 3) may not be used.

The first bonding structure 190 may include a first bonding insulating layer 191 disposed on the first wiring structure 120, and first bonding pads 195 electrically connected to the first wiring layer 125 on a bonding surface of the first bonding insulating layer 191. The first bonding pads 195 may have a surface that may be substantially flat with the bonding surface of the first bonding insulating layer 191.

Similarly thereto, the second bonding structure 290 may include a second bonding insulating layer 291 disposed on the second wiring structure 220, and second bonding pads 295 electrically connected to the second wiring layer 225 on a bonding surface of the second bonding insulating layer 192. The second bonding pads 295 may have a surface that may be substantially flat with the bonding surface of the second bonding insulating layer 292.

The first and second bonding structures 190 and 290 may be hybrid bonded through a high-temperature annealing process while in a bonded state with each other. Hybrid bonding may include inter-metallic bonding of the first and second bonding pads 195 and 295 and inter-dielectric bonding of the first and second bonding insulating layers 191 and 291. By the hybrid bonding, the first substrate structure 100 and the second substrate structure 200 may not only be firmly bonded to each other, but also the first and second wiring layers 125 and 225 may be electrically connected through inter-metallic bonding. Therefore, the first and second bonding pads 195 and 295 may replace the first connection structures 550 used to connect the first and second wiring layers 125 and 225 (see FIG. 3).

Referring to FIG. 9A, the anti-reflective laminate 310 may include a first insulating film 311, a conductive film 312, a second insulating film 313, and a third insulating film 314 sequentially stacked on the second surface 110b of the substrate 110.

Referring to FIGS. 9A and 9B, the first insulating film 311 may be configured to have an open region OP1 opening the PD isolation pattern 150 located inwardly of the backside contact 360 in the light-blocking region OB. The conductive film 312 formed on the first insulating film 311 may be in contact with the PD isolation patterns 150 through the opening OP1 of the first insulating film 311.

The PD isolation pattern 150 opened by the open region OP1 may be provided as a good-quality discharge path for the conductive film 312.

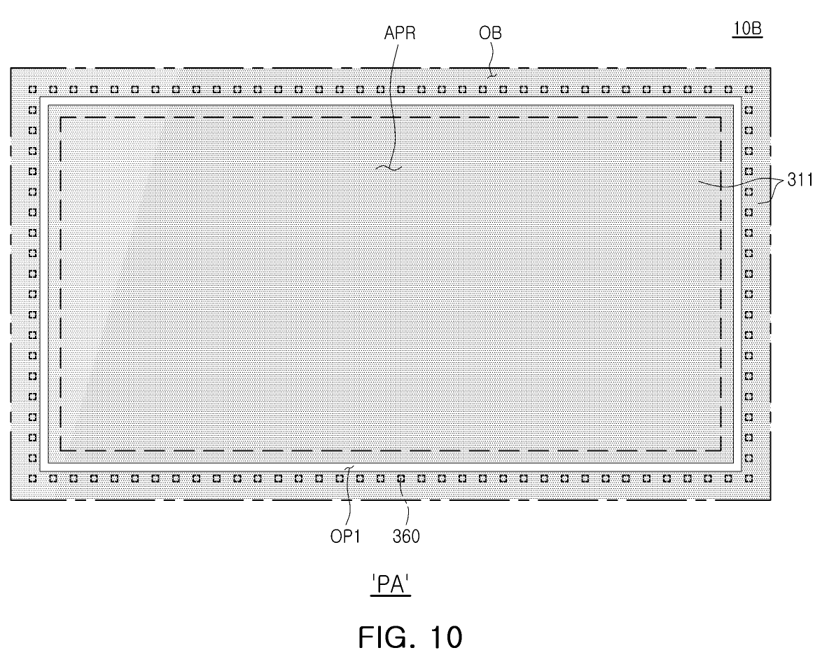

FIG. 10 is a plan view illustrating a pixel region PA of the image sensor 10B of FIG. 8.

Referring to FIG. 10 together with FIG. 9B, an open region OP1 of the first insulating film 311 may be continuously formed to surround the active pixel region APR inwardly of the backside contact 360.

The anti-reflective laminate 310 may secure a stable discharge path through a light-blocking region OB located on the entire periphery of the active pixel region APR.

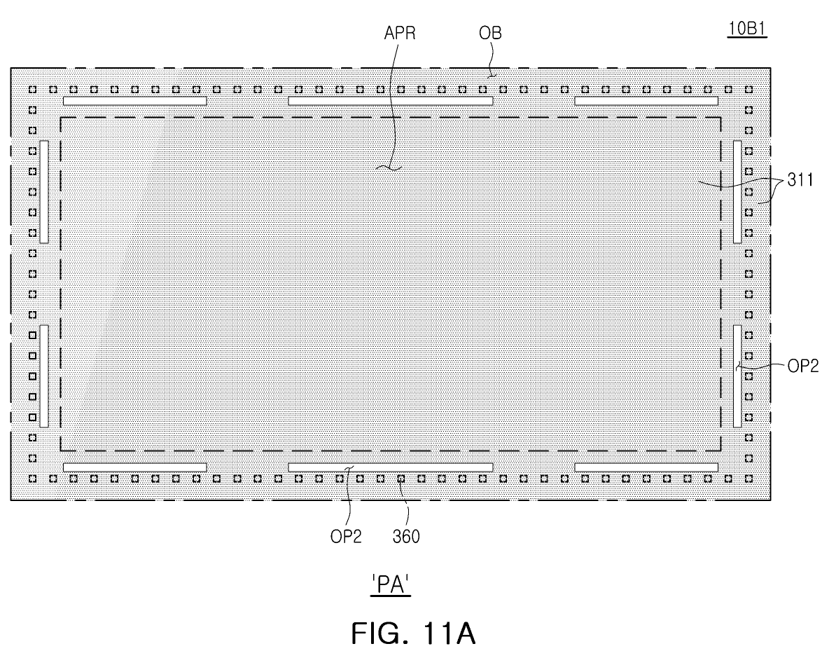

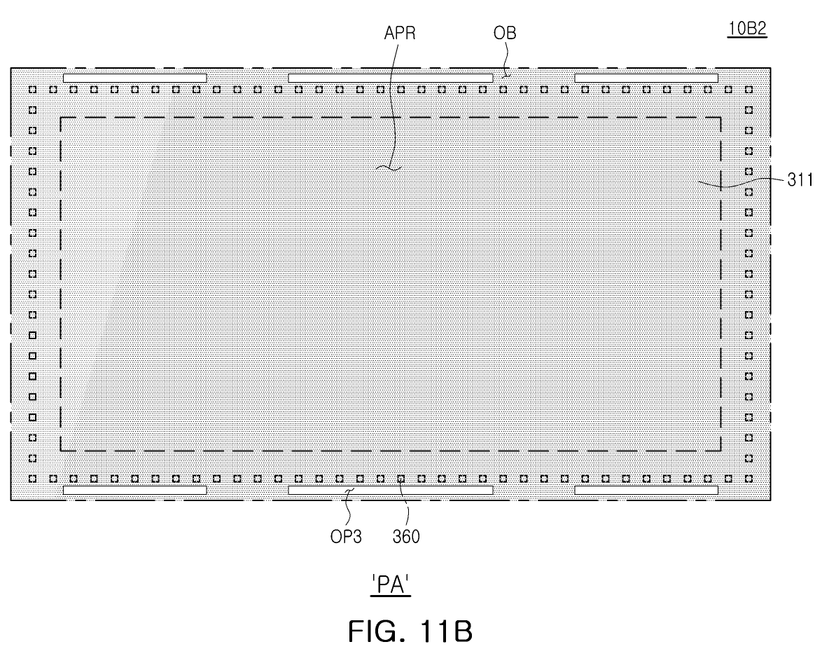

The first insulating film 311 may be exemplified as having an open region OP1 that may extend continuously to surround the active pixel region APR in the light-blocking region OB. However, embodiments of the present disclosure are not limited thereto. In some embodiments, the open region providing the discharge path for the conductive film 312 may be changed to have various shapes as illustrated in FIGS. 11A and 11B.

Referring to FIG. 11A, an image sensor 10C1, according to an embodiment, may include a first insulating film 311 having an open region OP2 of a different shape in a light-blocking region OB. The open region OP2 of the first insulating film 311 may have a plurality of open patterns arranged along the backside contacts 360. Each of the plurality of open patterns may be formed to open a region of the second surface 110b of the substrate 110 located inwardly of the backside contacts (360) (e.g., a region close to the active pixel region APR) and may be arranged to surround the active pixel region APR.

In contrast, referring to FIG. 11B, an image sensor 10C2, according to an embodiment, may include a first insulating film 311 having an open region of a different shape OP3. The opening OP3 of the first insulating film 311 may have a plurality of open patterns that open the portions of the PD isolation pattern 150 located inwardly of the backside contacts 360 (e.g., a region close to the peripheral region CA). Instead of surrounding entire sides of the active pixel array APR, the open patterns may be arranged along two long sides of the active pixel array APR.

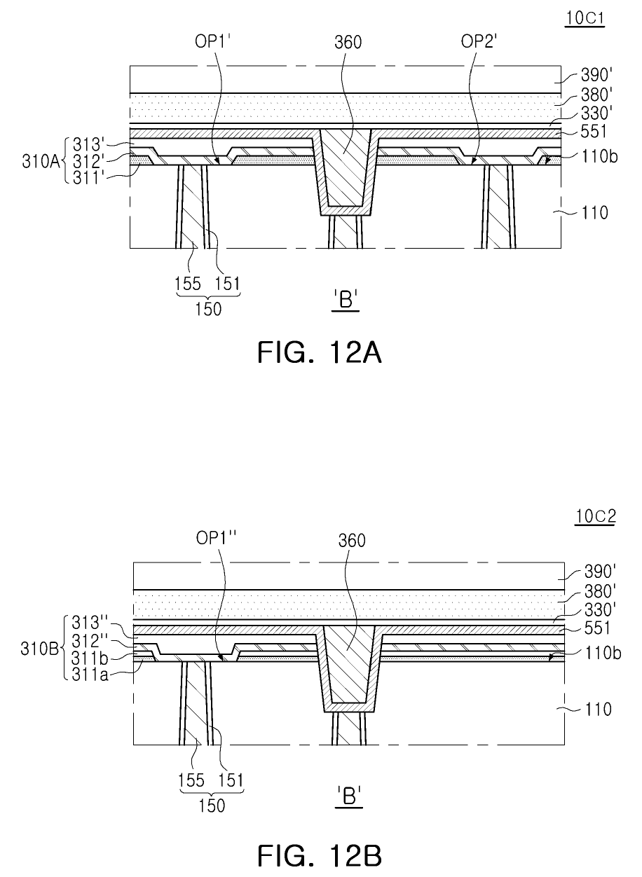

Although the anti-reflective laminate 310 has been described as a four-layer structure in which the conductive film 312 is positioned on the first insulating film 311, which is the lowermost layer, embodiments of the present disclosure are not limited thereto. For example, the anti-reflective laminate 310 may be changed to various layer structures. FIGS. 12A and 12B are enlarged cross-sectional views illustrating a portion of an image sensor, according to an embodiment.

The image sensors 10C1 and 10C2 described with reference to FIGS. 12A and 12B may include and/or may be similar in many respects to the image sensors described above with reference to FIGS. 4A and 7A, and may include additional features not mentioned above. Consequently, repeated descriptions of the image sensors 10C1 and 10C2 described above with reference to FIGS. 4A and 7A may be omitted for the sake of brevity.

The image sensor 10C1 described with reference to FIG. 12A may include and/or may be similar in many respects to the image sensor 10 described above with reference to FIGS. 1-3, 4A, 4B, and 5, and may include additional features not mentioned above. For example, the image sensor 10C1 may include a three-layer anti-reflective laminate 310A, and the first insulating film 311' has first and second open regions OP1' and OP2' respectively connected to PD isolation pattern 150 located inwardly and outwardly of the backside contact 360. Furthermore, components of the image sensor 10C1 may include and/or may be similar in many respects to the components of the image sensor 10 described above with reference to FIGS. 1-3, 4A, 4B, and 5, and may include additional features not mentioned above. Consequently, repeated descriptions of the image sensor 10C1 described above with reference to FIGS. 1-3, 4A, 4B, and 5 may be omitted for the sake of brevity.

The anti-reflective laminate 310A may have a three-layer structure including a first insulating film 311', a conductive film 312', and a second insulating film 313' sequentially stacked on the second surface 110b of the substrate 110. In some embodiments, the first insulating film 311' may be and/or may include an aluminum oxide (AlOₓ), and the conductive film 312' may include titanium oxide (TiO₂) or tantalum oxide (TaO₂). In addition, the second insulating film 313' may include, but not limited to, a silicon oxide (SiO), a hafnium oxide (HfOₓ), or the like.

In an embodiment, the first insulating film 311' may be configured to have first and second open regions OP1' and OP2' that respectively open the PD isolation pattern 150 located respectively inwardly and outwardly of the backside contact 360 in the light-blocking region OB. Similarly to the embodiments described above, the conductive film 312' formed on the first insulating film 311' may be connected to the PD isolation pattern 150 through the first and second open regions OP1' and OP2' of the first insulating film 311', respectively, and may discharge charges accumulated in the conductive film 312' through the PD isolation pattern 150.

The image sensor 10C2 described with reference to FIG. 12B may include and/or may be similar in many respects to the image sensor 10 described above with reference to FIGS. 1-3, 4A, 4B, and 5, and may include additional features not mentioned above. For example, the image sensor 10C2 may include an anti-reflective laminate 310B in which a position of the conductive film 312 is different, and the first and second lower insulating films 311a and 311b may have open regions OP1'' respectively connected to PD isolation pattern 150 located inwardly of the backside contact 360. Furthermore, components of the image sensor 10C1 may include and/or may be similar in many respects to the components of the image sensor 10 described above with reference to FIGS. 1-3, 4A, 4B, and 5, and may include additional features not mentioned above. Consequently, repeated descriptions of the image sensor 10C1 described above with reference to FIGS. 1-3, 4A, 4B, and 5 may be omitted for the sake of brevity.

The anti-reflective laminate 310B may have a four-layer structure including a first lower insulating film 311a, a second lower insulating film 311b, a conductive film 312'', and an upper insulating film 313 sequentially stacked on the second surface 110b of the substrate 110.

In an embodiment, not only the first lower insulating film 311a, but also the second lower insulating film 311b may be configured to have open regions OP1'' that open the PD isolation pattern 150 located inwardly of the backside contact 360 in the light-blocking region OB. In an embodiment, the conductive film 312'' formed on the first and second lower insulating films 311a and 311b may be connected to the PD isolation pattern 150 through the open region OP1'' of the first and second lower insulating films 311a and 311b, and charges accumulated in the conductive film 312'' may be released through the PD isolation pattern 150.

As described above, similarly to the above-descried embodiments, anti-reflective laminates of various structures may also form an open region in at least one insulating film located below a conductive film, so that the open region may be provided as a discharge path for the conductive film.

As set forth above, according to the embodiments described above, an open region may be formed in an insulating film (e.g., aluminum oxide (AlOₓ)) disposed below a conductive film in a multilayer anti-reflective structure of an image sensor, and the conductive film may provide a discharge path through the open region, thereby effectively discharging charges accumulated in the conductive film.

The various and beneficial advantages and effects of the present disclosure may not be limited to the above-described content, and may be more easily understood through description of specific embodiments of the present disclosure.

While embodiments have been illustrated and described above, it is to be apparent to those skilled in the art that modifications and variations may be made without departing from the scope of the present disclosure as defined by the appended claims.

What is claimed is:

1. An image sensor, comprising:
a stack structure comprising an active pixel region and a light-blocking region outside of the active pixel region,
wherein the stack structure further comprises:
a first substrate having a first surface and a second surface opposite to the first surface, and comprising photodiodes (PDs), each of unit pixels comprising at least one of the PDs;
a PD isolation pattern penetrating at least a portion of the first substrate in the active pixel region and the light-blocking region, and separating the PDs;
an anti-reflective laminate in the light-blocking region comprising a lower insulating film and a conductive film sequentially stacked on the second surface of the first substrate; and
a light blocking layer on the anti-reflective laminate,
a second substrate on the first surface of the first substrate and comprising logic elements configured to drive the unit pixels,
wherein the lower insulating film comprises an open region opening the second surface of the first substrate in the light-blocking region, and
wherein the conductive film is coupled with the second surface of the first substrate through the open region of the lower insulating film.

2. The image sensor of claim 1, wherein an exposed region of the PD isolation pattern is exposed on the second surface of the first substrate through the open region of the lower insulating film, and
wherein the conductive film is coupled with the exposed region of the PD isolation pattern.

3. The image sensor of claim 1, wherein the conductive film comprises at least one of titanium oxide (TiO₂), tin oxide (SnO₂), tantalum oxide (TaO₂), or zinc oxide (ZnO).

4. The image sensor of claim 3, wherein the lower insulating film comprises aluminum oxide (AlOₓ).

5. The image sensor of claim 1, wherein the anti-reflective laminate further comprises a plurality of upper insulating films on the conductive film, and
wherein the plurality of upper insulating films have different refractive indices.

6. The image sensor of claim 1, wherein the anti-reflective laminate further comprises an upper insulating film between the lower insulating film and the conductive film, and having an open region corresponding to the open region of the lower insulating film.

7. The image sensor of claim 1, further comprising:
backside contacts at least partially surrounding the active pixel region in the light-blocking region.

8. The image sensor of claim 7, wherein the open region of the lower insulating film at least partially surrounds the backside contacts in a plan view.

9. The image sensor of claim 7, wherein the open region of the lower insulating film extends along the backside contacts in a plan view.

10. The image sensor of claim 7, wherein the open region of the lower insulating film is disposed in at least one of an inner region or an outer region, based on the backside contacts in a plan view.

11. The image sensor of claim 1, wherein the stack structure further comprises a connection region and a pad region sequentially disposed outwardly of the light-blocking region in a plan view.

12. The image sensor of claim 11, wherein the stack structure further comprises:
first connection structures at least partially penetrating through the first substrate and coupled with the second substrate, in the connection region,
an external bonding pad located on the second surface of the first substrate, in the pad region, and
a second connection structure at least partially penetrating through the first substrate on a side of the external bonding pad and coupling the external bonding pad with the second substrate, in the pad region.

13. The image sensor of claim 11, wherein the stack structure further comprises:
a first bonding structure on the second surface of the first substrate, and a second bonding structure on the second substrate,
wherein the first bonding structure comprises a first bonding insulating layer on the first substrate and first bonding pads within the first bonding insulating layer, and
wherein the second bonding structure comprises a second bonding insulating layer disposed on the second substrate and bonded to the first bonding insulating layer, and second bonding pads respectively bonded to the first bonding pads within the second bonding insulating layer.

14. The image sensor of claim 13, wherein the stack structure further comprises:
an external bonding pad disposed on a region of the second substrate exposed by a pad opening at least partially penetrating through the first substrate in the pad region.

15. An image sensor, comprising:
a stack structure comprising an active pixel region and a light-blocking region outside of the active pixel region,
wherein the stack structure further comprises:
a first substrate having a first surface and a second surface opposite to the first surface, and comprising photodiodes (PDs), each of unit pixels comprising at least one of the PDs;
a PD isolation pattern penetrating at least a portion of the first substrate in the active pixel region and the light-blocking region, and separating the PDs;
backside contacts extending from the second surface of the first substrate in the light-blocking region and coupled with a region of the PD isolation pattern;
an anti-reflective laminate in the light-blocking region comprising a first insulating film, a conductive film, and a second insulating film sequentially stacked on the second surface of the first substrate;
color filters corresponding to each of the unit pixels and disposed on the anti-reflective laminate of the active pixel region;
a light blocking layer on the anti-reflective laminate and
a second substrate on the first surface of the first substrate, and comprising logic elements configured to drive the unit pixels,
wherein the first insulating film comprises an open region opening another region of the PD isolation pattern in the light-blocking region, and
wherein the conductive film is coupled with another region of the PD isolation pattern through the open region of the first insulating film.

16. The image sensor of claim 15, wherein the first insulating film comprises an aluminum oxide (AlOₓ),
wherein the conductive film comprises at least one of titanium oxide (TiO₂) or tantalum oxide (TaO₂), and
wherein the second insulating film comprises a metal oxide.

17. The image sensor of claim 15, wherein the anti-reflective laminate further comprises a third insulating film on the second insulating film,
wherein the second insulating film comprises a silicon oxide (SiO), and
wherein the third insulating film comprises a hafnium oxide (HfOₓ).

18. The image sensor of claim 16, wherein the open region of the first insulating film at least partially surrounds a periphery of the active pixel region in a plan view.

19. An image sensor, comprising:
a stack structure comprising an active pixel region in which a plurality of pixels are defined, and a light-blocking region outside of the active pixel region,
wherein the stack structure further comprises:
a first substrate having a first surface and a second surface, opposite to the first surface, and comprising photodiodes (PDs), each of the plurality of pixels comprising at least one of the PDs;
a PD isolation pattern penetrating at least a portion of the first substrate in the active pixel region and the light-blocking region, and separating the PDs;
an anti-reflective laminate comprising a first insulating film, a conductive film, and a second insulating film sequentially stacked on the second surface of the first substrate;
a first wiring structure on the first surface of the first substrate, and comprising a first wiring layer and a first interlayer dielectric;
a second substrate disposed on the first wiring structure, and comprising logic elements for driving the plurality of pixels; and
a second wiring structure between the second substrate and the first wiring structure, and comprising a second wiring layer and a second interlayer dielectric,
wherein the first insulating film comprises an open region opening at least one of the second surface of the first substrate or the PD isolation pattern in the light-blocking region, and
wherein the conductive film is coupled with a region of the at least one of the second surface or the PD isolation pattern opened through the open region.

20. The image sensor of claim 19, wherein the conductive film comprises at least one of titanium oxide (TiO₂), tin oxide (SnO₂), tantalum oxide (TaO₂), or zinc oxide (ZnO).
